(19) United States
(12) Patent Application Publication
(10) Pub. No.: US 2016/0025790 A1
(43) Pub. Date: Jan. 28, 2016

(54) SHORT DETECTION BUS

(71) Applicant: CMC INDUSTRIAL ELECTRONICS LTD., Burnaby (CA)

(72) Inventors: Douglas FORST, North Vancouver (CA); Vladimir ABRAMOV, Langley (CA)

(21) Appl. No.: 14/340,301

(22) Filed: Jul. 24, 2014

(51) Int. Cl. G01R 31/02; G01R 31/04; H02H 3/08

(52) U.S. Cl. CPC G01R 31/025; H02H 3/08; G01R 31/04

(57) ABSTRACT

A short-circuit test system and method of use wherein the system generally comprises an interface circuitry for communication of voltage signals over a serial bus with at least one bus sensor. The interface circuitry generally comprises at least one bus sensor, a means to measure and compare input voltage to a predefined value, a means to temporarily disable the bus sensor when the input voltage is less than the predefined value, and an evaluation logic to determine when a short-circuit condition exists on the bus sensor.

### BACKGROUND OF THE INVENTION

1. Field of Invention

The present invention relates to the field of electronic circuitry. More specifically, the present invention relates to a short-circuit detection system, device and method of use as it relates to short-circuit detection in an interface circuitry.

2. Description of Related Art

A busbar, sometimes shortened to “bus” is an electrical conductor that is maintained at a specific voltage and is capable of carrying a voltage current and is usually used to make a common connection between several circuits in a system. A common bus is used to monitor a series of bus sensors in order to reduce wiring to hazardous locations. However, when a common bus is used in a circuitry system, if one bus sensor experiences a low-resistance connection between two points in the electric circuit it usually results in either excessive current flow that can cause damage to the circuitry system or in a circuit that draws current away from the original pathways and components, otherwise known as a “short-circuit.” In a traditional bus interface or bus circuitry system, if one bus sensor creates a short-circuit it causes all the bus sensors to also short-circuit, thereby losing all sensors.

### SUMMARY OF THE INVENTION

It is the object of the present invention to address several challenges in previous attempts to detect short-circuits in bus sensors to prevent failure of all bus sensors on a common bus. The present invention is a system, device and method for detecting short-circuits in an interface circuitry for communication signals over a serial bus with at least one bus sensor.

In one embodiment of the present invention, a bus interface device is disclosed wherein the device generally comprises at least one bus sensor, a means to measure and compare input voltage to a predefined value, a means to temporarily disable the bus sensor when the input voltage is less than the predefined value, and an evaluation logic to determine when a short-circuit condition exists on the bus sensor. In a second embodiment of the present invention, a short-circuit test system is disclosed wherein the system generally comprises an interface circuitry for communication of voltage signals over a serial bus with at least one bus sensor.

In a third embodiment of the present invention, a method to evaluate a short-circuit in a bus interference device is disclosed wherein the method generally comprises comparing input voltage to an internal reference voltage to generate a control signal that indicates a possible short-circuit condition exists on a bus sensor; identifying one or more short-circuited bus sensors; temporarily disabling all identified short-circuited bus sensor; and testing each identified short-circuited bus sensor against at least one control signal indicative of whether a short-circuit condition exists on a bus sensor.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention wherein similar characters of reference denote corresponding parts in each view,

FIG. 1 is a flow chart demonstrating the present invention.

FIG. 2 is a diagram of a bus for use in the present invention.

FIG. 3 is a process control diagram used in the channel control of the bus of FIG. 2.

### DETAILED DESCRIPTION

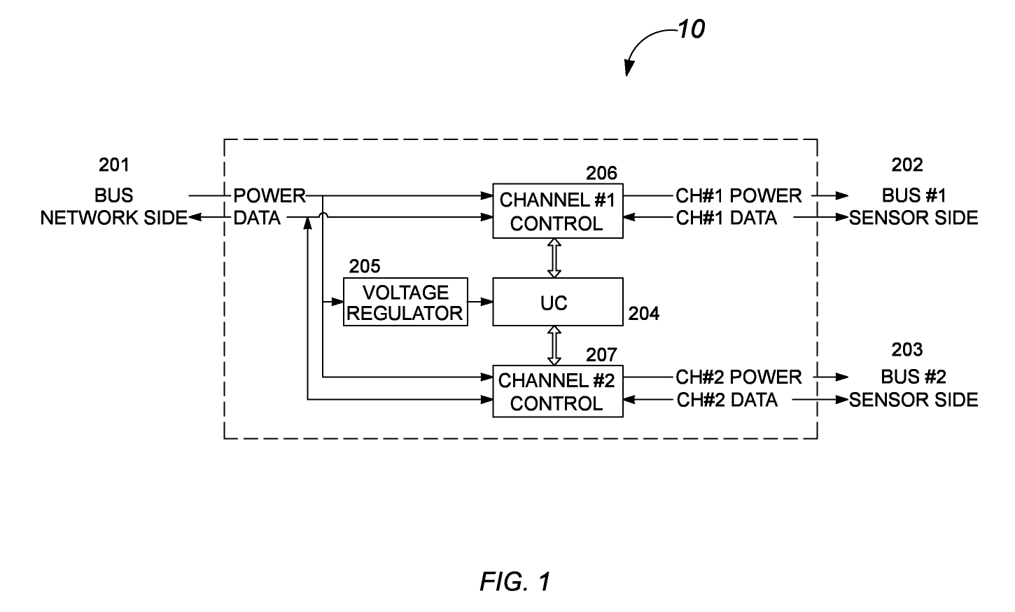

With reference to FIG. 1, an apparatus for detecting a sensor short is illustrated generally at 10. The apparatus receives a network side power input and data output 201 from a network (not shown) as is commonly known and interfaces with a plurality of sensor side data and power interfaces 202 ad 203.

Although only two sensor side outputs are illustrated in FIG. 1, it will be appreciated that more than two may also be utilized. The apparatus interfaces with a plurality of sensors through the sensor side interfaces, 202 and 203 and is adapted to detect and isolate a short circuited sensor as will be more fully described below. The apparatus comprises a control channel module for each sensor, 206 and 207 respectively and a processing circuit 204 for monitoring the data and power outputted to and received from the sensors at the sensor interface 202. As illustrated in FIG. 1, the apparatus 10 may further include a voltage regulator 205 for the processing circuit.

In the present embodiment, the processor circuit includes a microprocessor or other suitable processor circuit as are generally known in the art. More generally, in this specification, including the claims, the term “processor circuit” is intended to broadly encompass any type of device or combination of devices capable of performing the functions described herein, including (without limitation) other types of microprocessors, microcontrollers, other integrated circuits, other types of circuits or combinations of circuits, logic gates or gate arrays, or programmable devices of any sort, for example, either alone or in combination with other such devices located at the same location or remotely from each other, for example. Additional types of processor circuits will be apparent to those ordinarily skilled in the art upon review of this specification, and substitution of any such other types of processor circuits is considered not to depart from the scope of the present invention as defined by the claims appended hereto.

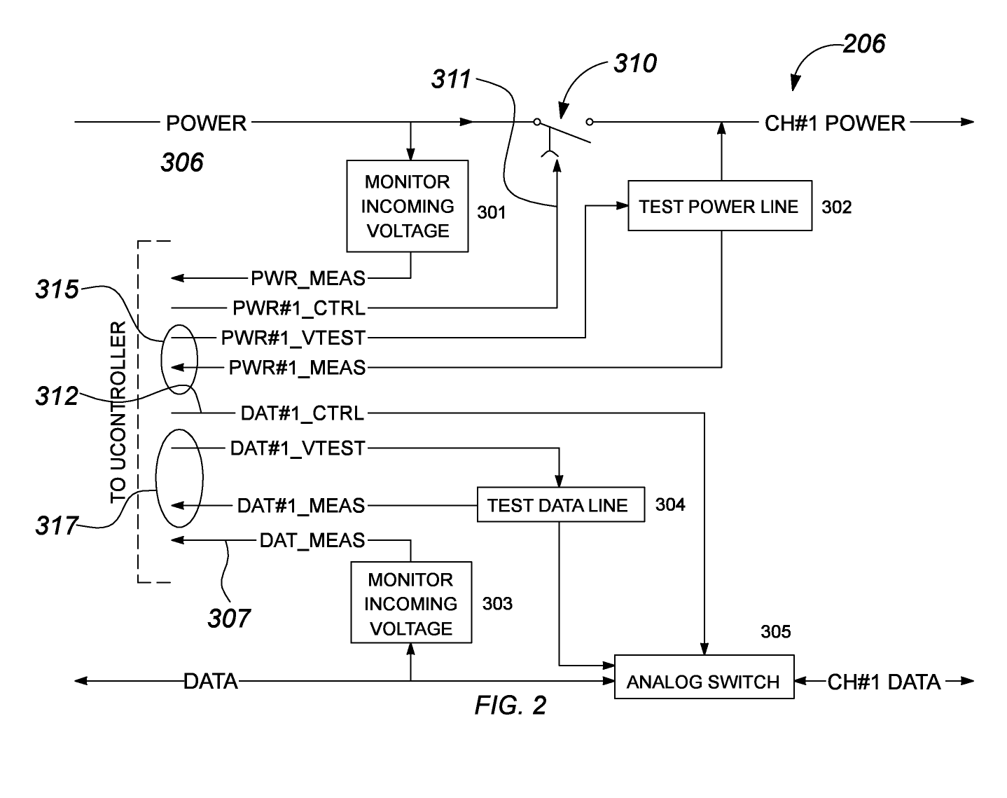

Turning now to FIG. 2, a view of one control channel module 206 is illustrated. It will be appreciated that although only the control channel module for the first sensor is illustrated, other control channel modules will also be similarly constructed. The control channel module 206 comprises a power line voltage monitor 301 and a data line voltage monitor 303. The power line and data line voltage monitors 301 and 303 are adapted to monitor or sample the voltage in the power and data lines to the sensor at the sensor interface 202 and output a signal to the processing circuit 204 through the power and data measurement connections, 306 and 307, respectively. The control channel module 206 also includes a power switch 310 such as by way of non-limiting example a Fairchild® part number FDN302P and an analog data switch 305 such as by way of non-limiting example a Texas Instrument® part number TS12A12511 adapted to interrupt power and data to and from the sensor upon receipt of a signal from the processing circuit 204 through control lines, 311 and 312, respectively in response to a detection of a drop in voltage in either the power or data line as detected by the power line voltage monitor or data line voltage monitor 301 or 303. As illustrated in FIG. 2. The control channel module 206 includes power and data test modules 302 and 304 adapted to test the continuity of the power and data lines of the sensor respectively in response to instructions received from the processing circuit through test channels 315 and 317.

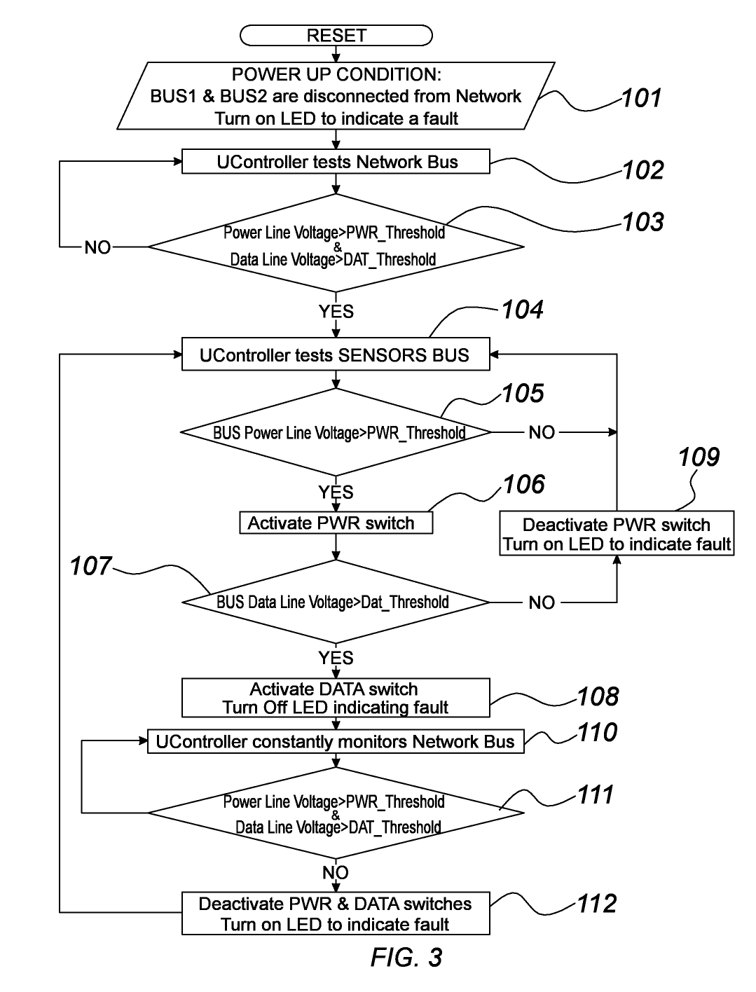

Turning now to FIG. 3, an exemplary embodiment of the system, method and device of the present invention is illustrated via flow chart. As illustrated in FIG. 3, the system initially receives a power up signal 101 at which time both the busses are disconnected from the network. In particular in this initial condition, the control switches 305 and 310 are open. Upon receiving a signal to power up, the system turns on a light or other suitable indicator to indicate a fault condition. Thereafter, as indicated at 102, the system measures the voltage at the network buss as measured by the power line and dataline voltage monitors 301 and 303. If the voltage to the power or data lines is greater than designated threshold amounts as indicated at 103, the system will proceed to test the sensor buss at 104. If one or both of the voltages are not above the designated thresholds, the system will continue to test the network bus in 102 and indicate a fault as set out above.

In step 105, the system measures the bus power line level at the power test module 302 to determine if the bus power line voltage is above a threshold amount. If the power line voltage is above the threshold, the power switch 310 is activated in step 106 otherwise, the system retests the sensor bus in 104. Once the power has been reactivated, the system test the data line voltage though the test data module 304 to determine if it is above a desired threshold. If the data line voltage is above the threshold, the data switch 305 is turned on in 108 and the system then proceeds to continually monitor the network buss in 110. If the data line voltage is too low, the system deactivates the power switch 310 in 109 and rechecks the sensor bus in 104. In normal operation, the system will continuously monitor the power line voltage and data line voltage at 110. If both remain above the desired threshold as determined at 111, the system remains on and continues to monitor. If either level drops below the threshold, the power and data switches 310 and 305 are switched of and a fault indicated at 112.

For the purposes of promoting an understanding of the principles of the invention, reference has been made to the preferred embodiments illustrated in the drawings, and specific language has been used to describe these embodiments. However, this specific language intends no limitation of the scope of the invention, and the invention should be construed to encompass all embodiments that would normally occur to one of ordinary skill in the art. The particular implementations shown and described herein are illustrative examples of the invention and are not intended to otherwise limit the scope of the invention in any way. For the sake of brevity, conventional aspects of the method (and components of the individual operating components of the method) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections might be present in a practical device. Moreover, no item or component is essential to the practice of the invention unless the element is specifically described as “essential” or “critical”. Numerous modifications and adaptations will be readily apparent to those skilled in this art without departing from the spirit and scope of the present invention.

While specific embodiments of the invention have been described and illustrated, such embodiments should be considered illustrative of the invention only and not as limiting the invention as construed in accordance with the accompanying claims.

What is claimed is:

1. A bus interface device comprising:
at least one bus sensor;
a means to measure and compare input voltage to a predefined value;
a means to temporarily disable the bus sensor when the input voltage is less than the predefined value; and
an evaluation logic to determine when a short-circuit condition exists on the bus sensor.

2. The device of claim 1 further comprising a capacitor-input filter.

3. The device of claim 2 further comprising an analog-to-digital converter wherein the input voltage is filtered by the capacitor-input filter and an analog-to-digital converter coverts filtered input voltage to a digital number.

4. The device of claim 3 wherein the means to measure and compare input voltage comprises comparing the digital number to the predefined value.

5. The device of claim 1 further comprises a processor circuit operable to compare a measured input voltage against at least one voltage control signal.

6. The device of claim 5 wherein the processor circuit determines that a short-circuit condition exists on a bus sensor when input voltage is less than the voltage control signal.

7. The device of claim 6 further comprising a means to disable the bus sensor with a short circuit condition.

8. The device of claim 7 wherein the bus sensor remains disabled when a short-circuit condition is indicated by at least one of the control signals.

9. The device of claim 5 wherein the bus sensor is re-enabled when the processor circuit determines that a short-circuit condition does not exist on a bus sensor when input voltage exceeds the voltage control signal.

10. A short-circuit test system comprising:
an interface circuitry for communicating signals over a serial bus with at least one bus sensor, wherein the interface circuitry comprises:
at least one bus sensor;
a means to measure and compare input voltage to a predefined value;
a means to temporarily disable a bus sensor when the input voltage is less than the predefined value; and
an evaluation logic to determine when a short-circuit condition exists on a bus sensor.

11. The system of claim 10 further comprising a capacitor-input filter and an analog-to-digital converter wherein the input voltage is filtered by the capacitor-input filter and an analog-to-digital converter coverts filtered input voltage to a digital number.

12. The system of claim 11 wherein the means to measure and compare input voltage comprises comparing the digital number to the predefined value.

13. The system of claim 12 further comprises a processor circuit operable to compare a measured input voltage against at least one voltage control signal.

14. The system of claim 10 wherein the processor circuit determines that a short-circuit condition exists on a bus sensor when input voltage is less than the voltage control signal.

15. The system of claim 14 further comprising a means to permanently disable the bus sensor with a short circuit condition.

16. The system of claim 15 wherein the bus sensor remains disabled when a short-circuit condition is indicated by at least one of the control signals.

17. The system of claim 13 wherein the bus sensor is re-enabled when the evaluation logic determines that a short-circuit condition does not exist on a bus sensor when input voltage exceeds the voltage control signal.

18. A method to evaluate a short-circuit in a bus interface device comprising:
comparing input voltage to an internal reference voltage to generate a control signal that indicates a possible short-circuit condition exists on a bus sensor;
identifying one or more short-circuited bus sensors;
temporarily disabling all identified short-circuited bus sensor; and
testing each identified short-circuited bus sensor against at least one control signal indicative of whether a short-circuit condition exists on a bus sensor.

19. The method of claim 18 further comprising repowering the identified short-circuited bus sensor when all control signals indicate that a short-circuit condition does not exist on the identified short-circuited bus sensor.

20. The method of claim 18 further comprising isolating the identified short-circuited bus sensors when at least one control signal indicates that a short-circuit condition exists.
